(19) United States
(12) Patent Application Publication
(10) Pub. No.: US 2021/0400911 A1
(43) Pub. Date: Dec. 30, 2021

(54) DROP FEED LINE DEVICE WITH PLANAR CIRCUIT BOARDS HAVING EMITTERS AND RECEIVERS

(71) Applicant: Hog Slat, Inc., Newton Grove, NC (US)

(72) Inventor: Timothy Glenn King, Coats, NC (US)

(21) Appl. No.: 16/916,189

(22) Filed: Jun. 30, 2020

(51) Int. Cl. A01K 5/02; H05K 5/00; G01V 8/20

(52) U.S. Cl. CPC A01K 5/0258; G01V 8/20; A01K 5/0291; H05K 5/0047

(57) ABSTRACT

Disclosed is a drop feed line device for automatically controlling flow of feed through a feed drop. The drop feed line device includes a drop body with an electrical box and a feed tube, as well as two planar circuit boards within respective sleeves removably positioned on opposite sides of the feed tube and in electrical communication with electronic components within the electrical box. In certain embodiments, the planar circuit boards include infrared emitters and receivers to electrically communicate across an interior channel of the feed tube. The electronic components are configured to transmit a signal to cease operation of an auger motor filling a drop feed line upon determining that all of the emitters cease to communicate with all of the receivers. The drop feed line device is cost effective and serviceable through the use of easily removable planar circuit boards, among other features and components.

### FIELD OF THE DISCLOSURE

The disclosure relates to a feed delivery system, and more particularly to a drop feed line device for a feed delivery system.

### BACKGROUND

Livestock feed systems allow for large scale, simultaneous delivery of livestock feed from a central storage container to multiple animals, which may be housed in separate enclosures and buildings at a farm or other livestock management facility. Some feed paths are formed by a plurality of tubes.

Feed systems may include feed drops (may also be referred to as feed outlets) to deliver feed to the tubing using gravity. Some feed drops may include a sensor to detect whether sufficient feed is present at the drop and/or to detect when feed has backed up within the feed tube. However, such feed drops may be expensive to manufacture and/or unreliable. For example, some feed drops include flexible circuit boards for mounting sensors, which are more expensive than planar circuit boards. Further, some such feed drops may include a removable tube section to accommodate the flexible circuit board, which adds to the structural complexity and cost of such a configuration.

No admission is made that any reference cited herein constitutes prior art. Applicant expressly reserves the right to challenge the accuracy and pertinency of any cited documents.

### SUMMARY

Disclosed is a drop feed line device for automatically controlling a flow of feed through a feed drop. The drop feed line device includes a drop body with an electrical box and a feed tube, as well as two planar circuit boards within respective sleeves removably positioned on opposite sides of the feed tube and in electrical communication with electronic components within the electrical box. In certain embodiments, the planar circuit boards include infrared emitters and receivers to electrically communicate across an interior channel of the feed tube. The electronic components are configured to transmit a signal to cease operation of an auger motor filling a drop feed line upon determining that all of the emitters cease to communicate with all of the receivers. The drop feed line device is cost effective and serviceable through the use of easily removable planar circuit boards, among other features and components.

One embodiment is directed to a drop feed line device including a drop body, a first planar circuit board, and a second planar circuit board. The drop body includes an electrical box and a feed tube defining an interior channel. The first planar circuit board is positioned at a first side of the feed tube. The first planar circuit board is in electronic communication with electronic components within the electrical box. The first planar circuit board includes at least one emitter. The second planar circuit board is positioned at a second side of the feed tube. The second planar circuit board is in electronic communication with the electronic components within the electrical box. The second planar circuit board includes at least one receiver to electronically communicate with the at least one emitter across the interior channel of the feed tube.

Another embodiment is directed to a drop feed line device. The drop feed line device includes a drop body including an electrical box including a first track and a second track. The drop body further includes a feed tube defining an interior channel. The feed tube includes a first side opening and a second side opening opposite the first side opening. The first side opening is proximate the first track and the second side opening is proximate the second track. The drop feed line device further includes a first protective sleeve removably engaged with the first track at a first side of the feed tube and positioned at the first side opening of the feed tube. The drop feed line device further includes a second protective sleeve removably engaged with the second track at a second side of the feed tube and positioned at the second side opening of the feed tube. The drop feed line device further includes a first planar circuit board positioned in the first protective sleeve at the first side of the feed tube. The first planar circuit board is in electronic communication with electronic components within the electrical box. The first planar circuit board includes at least one infrared emitter. The drop feed line device further includes a second planar circuit board positioned in the second protective sleeve at the second side of the feed tube. The second planar circuit board is in electronic communication with the electronic components within the electrical box. The second planar circuit board includes at least one infrared receiver to electronically communicate with the at least one infrared emitter across the interior channel of the feed tube.

Another embodiment is directed to a feed system. The feed system includes a drop feed line, an auger motor configured to transmit feed to and through the drop feed line, and a drop feed line device positioned in and defining at least a portion of the drop feed line. The drop feed line device includes a drop body, a first planar circuit board, a second planar circuit board, and a feed controller. The drop body includes an electrical box and a feed tube defining an interior channel. The first planar circuit board is positioned at a first side of the feed tube. The first planar circuit board is in electronic communication with electronic components within the electrical box. The first planar circuit board includes at least one emitter. The second planar circuit board is positioned at a second side of the feed tube. The second planar circuit board is in electronic communication with the electronic components within the electrical box. The second planar circuit board includes at least one receiver to electronically communicate with the at least one emitter across the interior channel of the feed tube. The feed controller is positioned within the electrical box. The feed controller is configured to determine if all of the at least one emitter of the first planar circuit board cease to communicate with all of the at least one receiver of the second planar circuit board. The feed controller is further configured to transmit a signal to the auger motor to cease operation of the auger motor filling the drop feed line upon determining that all of the at least one emitters cease to communicate with all of the at least one receivers.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

FIG. 1A is a side view of a portion of a feed system including a plurality of feed drops and a drop feed line device;

FIG. 1B is a side view of a portion of the feed system of FIG. 1A including the drop feed line device;

FIG. 2 is a partially translucent view of the drop feed line device of FIGS. 1A and 1B illustrating the drop body, protective sleeves, and planar circuit boards.

FIG. 3A is a side view of the drop feed line device of FIGS. 1A-2;

FIG. 3B is an exploded perspective view of the drop feed line device of FIG. 3A;

FIG. 4A is a perspective view of the drop body of the drop feed line device of FIGS. 1A-3B;

FIG. 4B is a partial side view of an electrical box of the drop body of FIG. 4A including tracks for the protective sleeves;

FIG. 4C is a cross-sectional view of the drop body of FIG. 4A;

FIG. 5A is a perspective view of an inner curved portion of the protective sleeve of the drop feed line device of FIGS. 1A-3B;

FIG. 5B is a perspective view of a planar portion of the protective sleeve of FIG. 5A;

FIG. 5C is a front view of the protective sleeve of FIG. 5A;

FIG. 5D is a side view of the protective sleeve of FIG. 5A illustrating a blind depth of an interior thereof;

FIG. 6A is an exploded view of a drop body, protective sleeves, and planar circuit boards of the drop feed line device of FIGS. 1A-3B;

FIG. 6B is an assembled view of the drop body, protective sleeves, and planar circuit boards of FIG. 6A;

FIG. 6C is a cross-sectional side view of the drop line device of FIG. 6A illustrating electronic communication between emitters and receivers of the planar circuit boards; and

FIG. 6D is a cross-sectional top view of the drop line device of FIG. 6A illustrating electronic communication between the emitters and receivers of the planar circuit boards.

### DETAILED DESCRIPTION

Reference will now be made in detail to the present preferred embodiments, examples of which are illustrated in the accompanying drawings. Whenever possible, the same reference numerals will be used throughout the drawings to refer to the same or like parts.

Terms such as “left,” “right,” “top,” “bottom,” “front,” “back,” “horizontal,” “parallel,” “perpendicular,” “vertical,” “lateral,” “coplanar,” and similar terms are used for convenience of describing the attached figures and are not intended to limit this description. For example, terms such as “left side” and “right side” are used with specific reference to the drawings as illustrated and the embodiments may be in other orientations in use. Further, as used herein, terms such as “horizontal,” “parallel,” “perpendicular,” “vertical,” “lateral,” etc., include slight variations that may be present in working examples.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Disclosed is a drop feed line device for automatically controlling a flow of feed through a feed drop. The drop feed line device includes a drop body with an electrical box and a feed tube, as well as two planar circuit boards within respective sleeves removably positioned on opposite sides of the feed tube and in electrical communication with electronic components within the electrical box. In certain embodiments, the planar circuit boards include infrared emitters and receivers to electrically communicate across an interior channel of the feed tube. The electronic components are configured to transmit a signal to cease operation of an auger motor filling a drop feed line upon determining that all of the emitters cease to communicate with all of the receivers. The drop feed line device is cost effective and serviceable through the use of easily removable planar circuit boards, among other features and components.

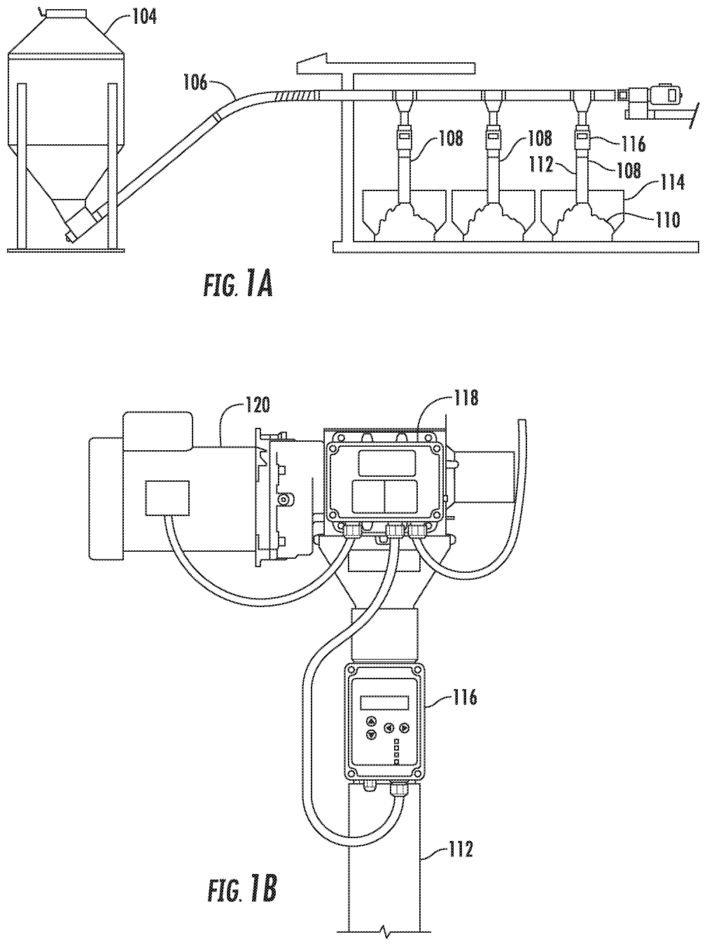

FIGS. 1A-1B are views of a feed system 100. Referring to FIG. 1A, the feed system 100 includes one or more feed hoppers 104, tubing 106 (may also be referred to as a chain disk line, chain disk tubing, etc.), and a plurality of feed drops 108 (may also be referred to as feed outlets). The feed hoppers 104 house feed (or other particulate) in bulk. The tubing 106 form a feed path for delivering the feed from the feed hopper 104 to the various feed drops 108.

One or more auger motors rotate an auger to deliver feed 110 from one or more of the feed hoppers 104 through the tubing 106 to one or more of the feed drops 108. Gravity draws the feed downward through a drop feed line 112 of the feed drop 108 into a bin 114. Feed 110 proceeds to flow through the drop feed line 112 until the bin 114 is filled, at which point, the feed 110 starts to back up through the drop feed line 112. Flow of feed 110 through the drop feed line 112 is controlled by a drop feed line device 116 which detects the presence of feed 110 in the drop feed line 112.

Referring to FIG. 1B, the drop feed line device 116 detects presence of feed 110 in the drop feed line 112 (e.g., when feed 110 has backed up through the drop feed line 112) and sends a signal to stop flow of feed 110 through the drop feed line 112. In particular, the drop feed line device 116 is positioned in and defines at least a portion of the drop feed line 112. In other words, the drop feed line device 116 is positioned in-line with the drop feed line 112. In certain embodiments, the drop feed line device 116 is in electrical communication with feed line control unit 118, which controls operation of an auger drive motor 120 of an auger. The auger drive motor 120 is configured to transmit feed 110 through the tubing 106 and through the drop feed line 112 of the feed drops 108. Accordingly, the drop feed line device 116 controls the feed line auger drive motor 120 by detecting presence of feed 110 in the drop feed line 112 to ensure that there is always feed 110 in the feed line (and correspondingly the bin 114) and to prevent backup of feed 110 beyond the drop feed line device 116 (and potential damage to the system). In certain embodiments, only the last feed drop 108 includes a drop feed line device 116 because if the last feed drop 108 is full of feed 110, then the rest of the feed drops 108 are presumably also full of feed 110. It is noted that the drop feed line device 116 may be used in a variety of feed systems (e.g., chain disk feed systems).

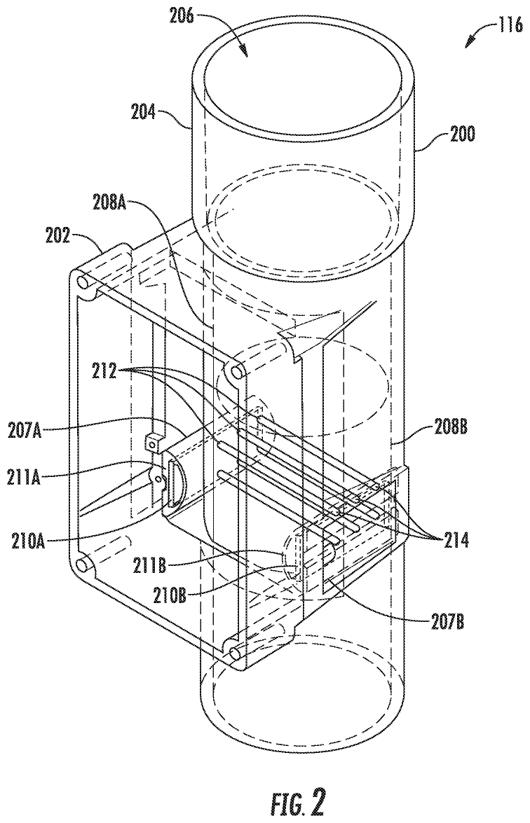

FIG. 2 is a partially translucent view of the drop feed line device 116. The drop feed line device 116 includes a drop body 200 having an electrical box 202 and a feed tube 204 defining an interior channel 206. The feed tube 204 includes a first side 208A and a second side 208B opposite the first side 208A.

The drop feed line device 116 includes a first planar circuit board 210A and a second planar circuit board 210B. The first planar circuit board 210A is positioned at the first side 208A of the feed tube 204. In certain embodiments, the first planar circuit board 210A is positioned within a first translucent protective sleeve 211A at the first side 208A of the feed tube 204. The first planar circuit board 210A is in electronic communication with electronic components within the electrical box 202. The first planar circuit board 210A includes at least one emitter 212.

The second planar circuit board 210B is positioned at the second side 208B of the feed tube 204. The second planar circuit board 210B is in electronic communication with electronic components within the electrical box 202. In certain embodiments, the second planar circuit board 210B is positioned within a translucent protective sleeve 211B at the second side 208B of the feed tube 204. The second planar circuit board 210B includes at least one receiver 214 to electronically communicate with the at least one emitter 212 across the interior channel 206 of the feed tube 204.

As explained in more detail below, if the emitters 212 and the receivers 214 of the first planar circuit board 210A and the second planar circuit board 210B are in electronic communication with one another, then the drop feed line device 116 is configured to continue operation of the auger drive motor 120 (see FIG. 1B). Once all of the emitters 212 and the receivers 214 cease electronic communication with one another, then the drop feed line device 116 ceases operation of the auger drive motor 120 because such blockage indicates that the feed 110 has backed up the drop feed line 112 (see FIG. 1B), and therefore the feed drop 108 has sufficient feed.

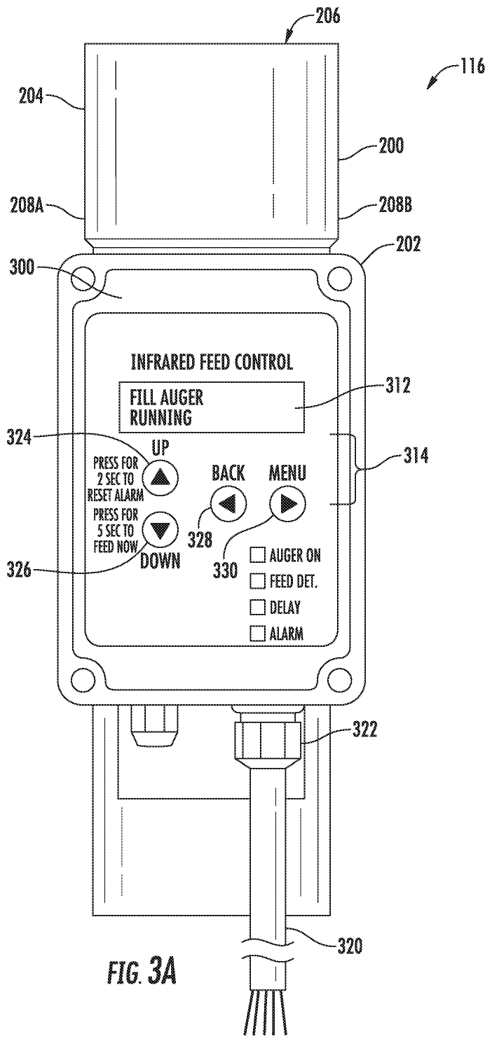

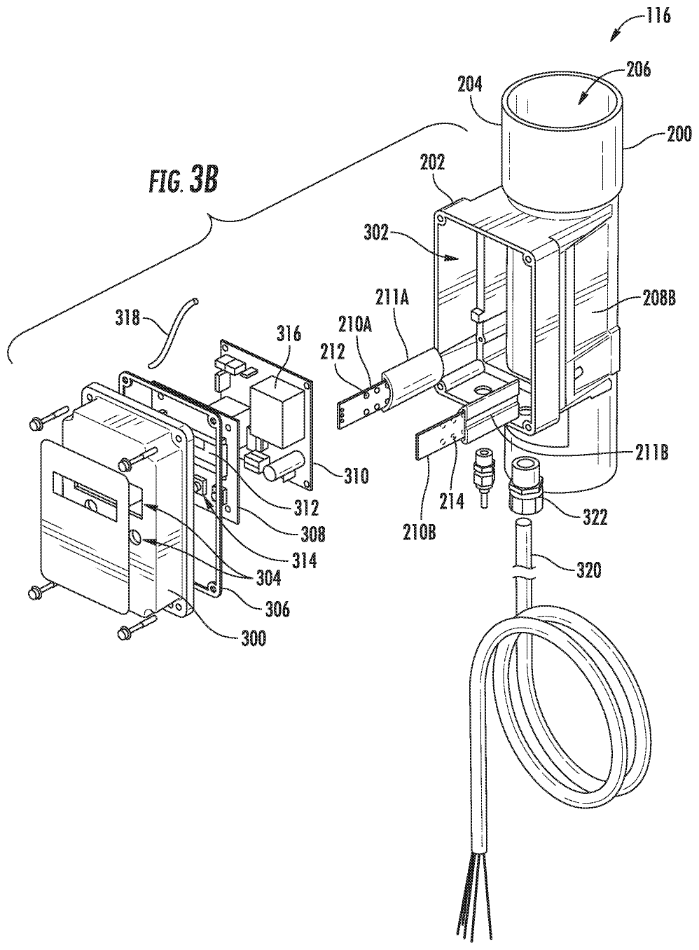

FIGS. 3A-3B are views of the drop feed line device 116 illustrating an assembled view and an exploded view. As similarly noted above, the drop feed line device 116 includes the drop body 200 having the feed tube 204. In particular, the interior channel 206 is configured to align with the drop feed line 112 such that feed 110 flows through the drop feed line 112 and the drop feed line device 116.

The drop feed line device 116 further includes the electrical box 202 and a cover 300 defining an electrical box interior 302. The cover 300 may include one or more apertures 304 to provide access to portions of electrical components within the electrical box interior 302. The drop feed line device 116 further includes a gasket 306 positioned between the electrical box 202 and the cover 300 to prevent water (and/or other liquids) from entering the electrical box interior 302.

The drop feed line device 116 includes electrical components positioned within the electrical box 202 including the first planar circuit board 210A and the second planar circuit board 210B. In certain embodiments, the electrical components further include a first printed circuit board (PCB) 308 and/or a second PCB 310. The first PCB 308 includes a controller (e.g., feed controller, microcontroller, etc.), a display 312 (e.g., LCD display), and/or user interface 314. The display 312 and/or user interface 314 are accessible through the apertures 304 of the cover 300. The second PCB 310 includes a power supply 316. The first PCB 308 and second PCB 310 are in electrical communication with one another, such as by a cable 318.

The drop feed line device 116 further includes an external electronic communication cable 320 extending from an electronic communication port 322 at a bottom of the electrical box 202. In certain embodiments, as noted above, the drop feed line device 116 is in electrical communication with a feed line control unit 118 (see FIG. 1B) via the external electronic communication cable 320.

The first planar circuit board 210A is positioned at the first side 208A of the feed tube 204. The first planar circuit board 210A is in electronic communication with electronic components within the electrical box 202. In certain embodiments, the first planar circuit board 210A is positioned within a first protective sleeve 211A at the first side 208A of the feed tube 204. The first planar circuit board 210A includes at least one emitter 212 (e.g., LED emitter, infrared emitter, etc.), such as a plurality of emitters 212.

The second planar circuit board 210B is positioned at the second side 208B of the feed tube 204. The second planar circuit board 210B is in electronic communication with electronic components within the electrical box 202. In certain embodiments, the second planar circuit board 210B is positioned within a protective sleeve 211B at the second side 208B of the feed tube 204. The second planar circuit board 210B includes at least one receiver 214 (e.g., infrared phototransistor, etc.), such as a plurality of receivers 214, to electronically communicate with the at least one emitter 212 across the interior channel 206 of the feed tube 204.

As explained in more detail below, if the emitters 212 of the first planar circuit board 210A and the receivers 214 of the second planar circuit board 210B are in electronic communication with one another, then the drop feed line device 116 is configured to continue operation of the auger drive motor 120 (see FIG. 1B). Once all of the emitters 212 and the receivers 214 cease electronic communication with one another, then the drop feed line device 116 ceases operation of the auger drive motor 120 because such blockage indicates that the feed 110 has backed up the drop feed line 112 (see FIG. 1B), and therefore the feed drop 108 has sufficient feed.

The feed controller is positioned within the electrical box 202. The feed controller is configured to determine if all of the plurality of emitters 212 of the first planar circuit board 210A cease to communicate with all of the plurality of receivers 214 of the second planar circuit board 210B, and transmit a signal to cease operation of an auger drive motor 120 filling a drop feed line 112 upon determining that all of the plurality of emitters 212 of the first circuit board 210A cease to communicate with all of the plurality of receivers 214 of the second circuit board 210B.

In certain embodiments, the user interface 314 includes an up button 324, a down button 326, a back button 328, and a forward button 330. In certain embodiments, depressing the up button 324 for two seconds resets an alarm of the drop feed line device 116. In certain embodiments, depressing the down button 326 for five seconds immediately starts the auger drive motor 120. In certain embodiments, the drop feed line device 116 is configured to only operate between predetermined hours (e.g., during the day only).

In certain embodiments, the display 312 is configured to change color to communicate a state of operation of the drop feed line device 116. In certain embodiments, the display 312 is configured to display a green background to indicate that the auger drive motor 120 is running. In certain embodiments, the display 312 is configured to display a purple background once the emitters 212 and receivers 214 detect feed 110 (e.g., cease communication therebetween). In certain embodiments, the display 312 is configured to display a blue background when a feed delay timer is activated. The feed delay timer (e.g., between 30 seconds and 12 hours) delays operation of the auger drive motor 120 once the emitters 212 and receivers 214 no longer detect feed 110 (e.g., resume communication therebetween). Once the feed delay timer has elapsed, the display 312 can turn green to indicate the auger drive motor 120 is running. In certain embodiments, the display 312 is configured to display a red background if the auger drive motor 120 is running beyond a predetermined maximum run time. If the predetermined maximum run time is exceeded, the auger drive motor 120 is turned off, an alarm is activated, and the display 312 displays a red background.

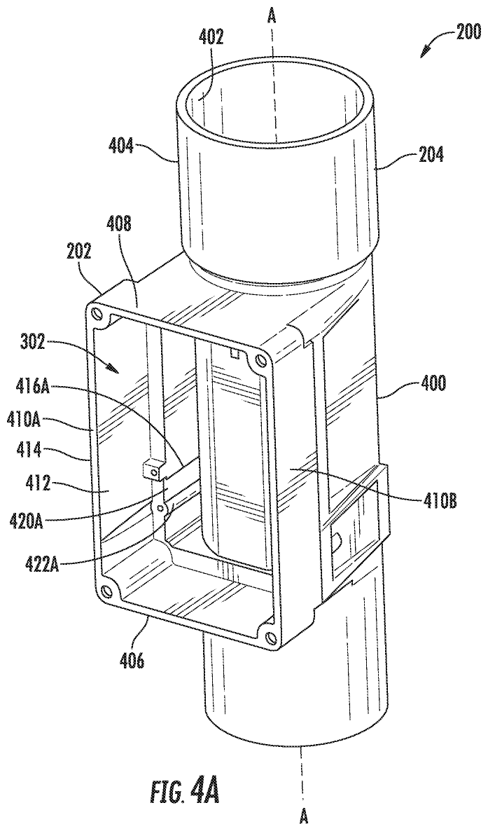

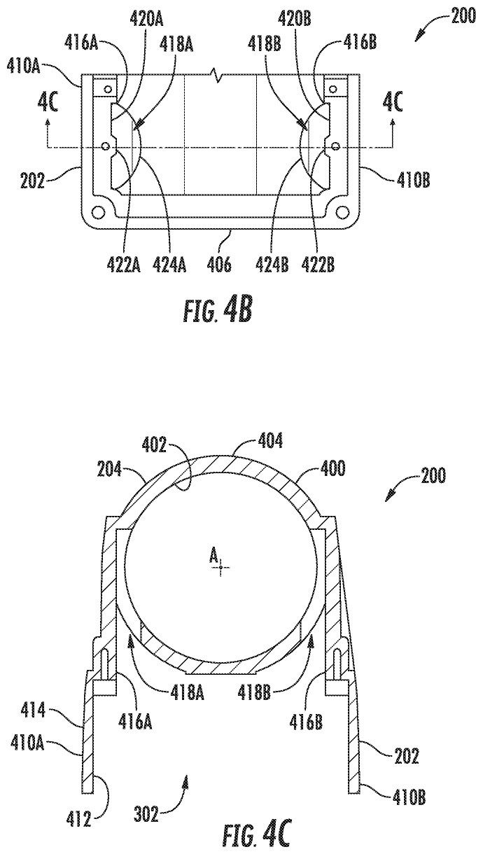

FIGS. 4A-4C are views of the drop body of the drop feed line device of FIGS. 2A-3B. As similarly noted above, the drop feed line device 116 includes a drop body 200 having a feed tube 204 to attach to and align with a drop feed line 112. The feed tube 204 includes a cylindrical sidewall 400 extending along axis A. The cylindrical sidewall 400 includes an internal surface 402 and an external surface 404.

The drop feed line device 116 further includes the electrical box 202 at an external surface 404 of the feed tube 204. In certain embodiments, the electrical box 202 integrally extends from an external surface 404 at a side of the drop feed line 112. In particular, the electrical box 202 includes a bottom wall 406, a top wall 408 (opposite the bottom wall 406), a first sidewall 410A, and a second sidewall 410B. The first and second sidewalls 410A, 410B extend between the bottom wall 406 and the top wall 408. The walls 406, 408, 410A, 410 include an internal surface 412 and an external surface 414. It is noted that the electrical box interior 302 is defined by the internal surface 412 of the walls 406, 408, 410A, 410 of the electrical box 202 and the external surface 404 of the feed tube 204.

The drop body 200 further includes a first track 416A and a second track 416B defined in at least a portion of the electrical box 202 and/or the feed tube 204. In other words, the electrical box 202 includes the first track 416A and the second track 416B opposite the first track 416A. The first and second tracks 416A, 416B are configured to receive and retain the protective sleeves 211A, 211B. The feed tube 204 of the drop body 200 includes a first side opening 418A defined in the cylindrical sidewall 400 and a second side opening 418B defined in the cylindrical sidewall 400 opposite the first side opening 418A. The first side opening 418A is proximate the first track 416A and the second side opening 418B is proximate the second track 416B.

In particular, the first track 416A is defined in at least a portion of the internal surface 402 of the first sidewall 410A. The first track 416A extends through the first side opening 418A defined in the cylindrical sidewall 400 and into an internal surface 402 of the cylindrical sidewall 400 of the feed tube 204. The first track 416A includes a first recess 420A and a first central rail 422A to align, guide, and retain the first protective sleeve 211A and first planar circuit board 210A therein. The first side opening 418A of the cylindrical sidewall 400 includes the first track 416A and a first curved portion 424A which corresponds to the shape of the first protective sleeve 211A.

Similarly, the second track 416B is defined in at least a portion of the internal surface 402 of the second sidewall 410B. The second track 416B extends through the second side opening 418B defined in the cylindrical sidewall 400 and into the internal surface 402 of the cylindrical sidewall 400 of the feed tube 204. The second track 416B includes a second recess 420B and a second central rail 422B to align, guide, and retain the second protective sleeve 211B and second planar circuit board 210B therein. The second side opening 418B of the cylindrical sidewall 400 includes the second track 416B and a second curved portion 424B which corresponds to the shape of the second protective sleeve 211B.

The first and second tracks 416A, 416B are positioned proximate the bottom wall 406 of the electrical box 202. However, the first and second tracks 416A, 416B could be positioned at a different location between the bottom wall 406 and the top wall 408 of the electrical box 202.

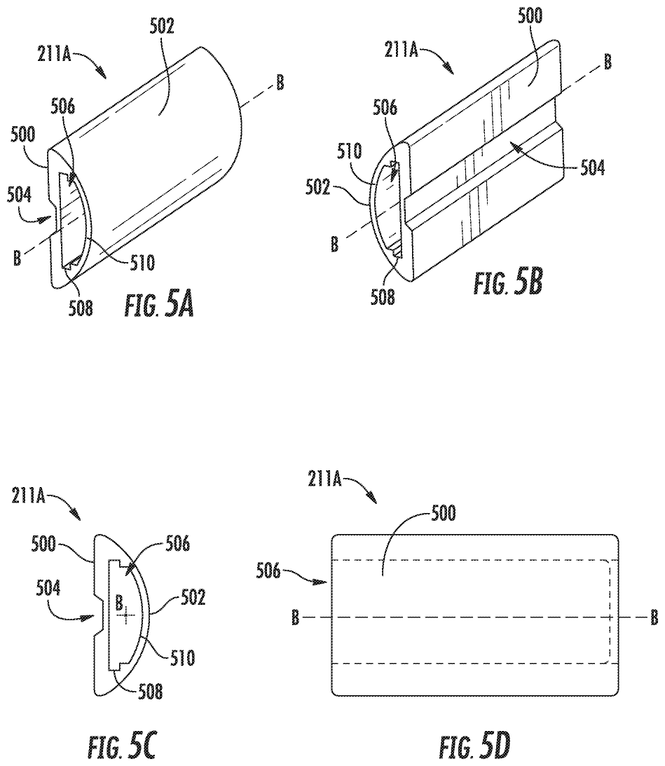

FIGS. 5A-5D are views of the first protective sleeve 211A of the drop feed line device 116 of FIGS. 2A-3B. The features discussed with respect to the first protective sleeve 211A also apply with respect to the second protective sleeve 211B.

The first protective sleeve 211A is cylindrically shaped with a generally planar face 500 and a curved portion 502 extending along axis B. In certain embodiments, such a configuration (without a change in curvature along axis B) facilitates communication between the emitters 212 and receivers 214 across the interior channel 206 of the feed tube 204. In particular, as the emitters 212 and receivers 214 are positioned on the first planar circuit board 210A, the cylindrical shape facilitates alignment of communication between the emitters 212 and receivers 214. Further, the curved portion 502 facilitates movement of the drop feed through the feed tube 204.

The planar face 500 includes a groove 504 extending along axis B, which may be used for aligning and/or engaging the first protective sleeve 211A relative to the drop body 200.

The first protective sleeve 211A includes an interior channel 506 having a blind depth. In this way, the first planar circuit board 210A can be easily inserted and/or removed from the first protective sleeve 211A. The interior channel 506 includes a retaining portion 508 and a clearance portion 510. The retaining portion 508 has a generally rectangular cross section and is configured to engage sides of the first planar circuit board 210A. The clearance portion 510 provides clearance for electronic components mounted to the first planar circuit board 210A.

The blind depth provided by the first protective sleeve 211A means that the first planar circuit board 210A can be fully inserted into the first protective sleeve 211A where doing so will provide an easy way to horizontally align the emitters 212 and/or receivers 214 between the first planar circuit board 210A and the second planar circuit board 210B across the interior channel 206 of the drop body 200.

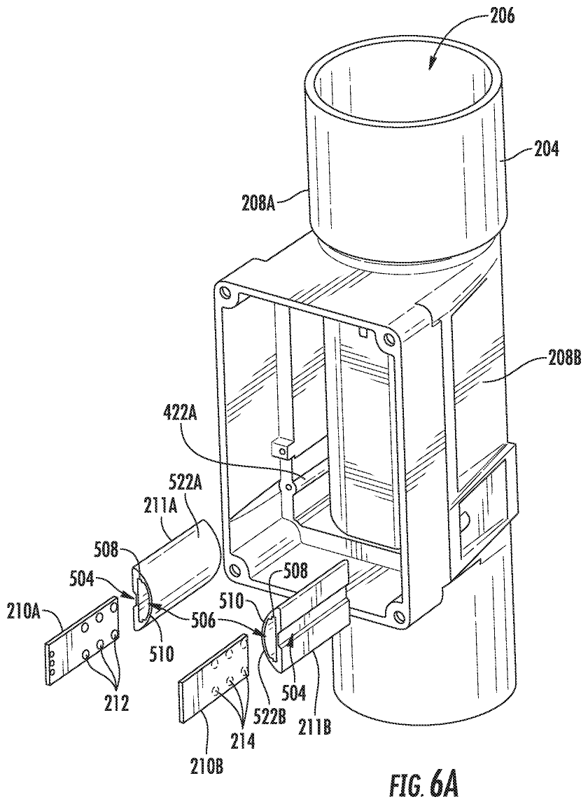

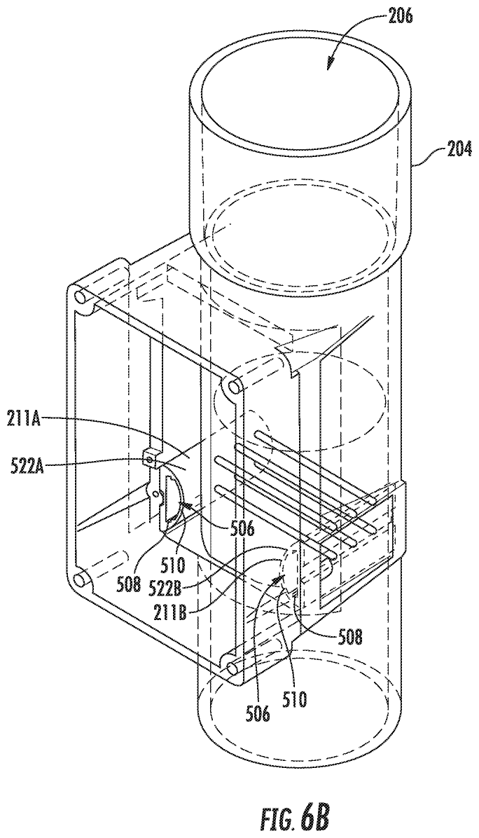

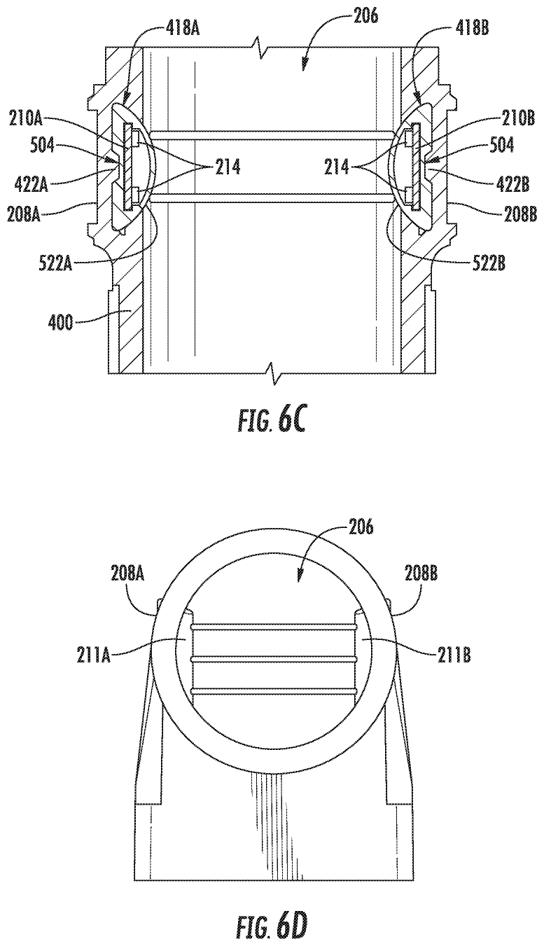

FIGS. 6A-6D are views of the drop line device of FIGS. 2A-3B illustrating assembly of and electronic communication between the emitters 212 and receivers 214 of the planar circuit boards 210A, 210B.

In certain embodiments, the first planar circuit board 210A includes at least one emitter 212, and the second planar circuit board 210B includes at least one receiver 214. In certain embodiments, the at least one emitter 212 of the first planar circuit board 210A includes an infrared emitter, and the at least one receiver 214 of the second planar circuit board 210B includes an infrared receiver.

In certain embodiments, the first planar circuit board 210A includes a plurality of emitters 212, and the second planar circuit board 210B includes a plurality of receivers 214. In certain embodiments, the at least one emitter 212 of the first planar circuit board 210A includes a plurality of emitters 212 including a first top row of infrared emitters 212 and a first bottom row of infrared emitters 212. In certain embodiments, the at least one receiver 214 of the second planar circuit board 210B includes a plurality of receivers 214 including a second top row of infrared receivers 214 and a second bottom row of infrared receivers 214. In certain embodiments, each of the first planar circuit board 210A and the second planar circuit board 210B includes at least one emitter 212 and at least one receiver 214 that are configured to communicate with corresponding emitters 212 and receivers 214 across the interior channel 206 of the drop body 200.

The first planar circuit board 210A inserts into the retaining portion 508 of the interior channel 506 of the first protective sleeve 211A, and the second planar circuit board 210B inserts into the retaining portion 508 of the interior channel 506 of the second protective sleeve 211B. The emitters 212 and/or receivers 214 extend into the clearance portion 510 of the interior channel 506 (see FIG. 6C).

The first protective sleeve 211A is inserted into the first track 416A of the drop body 200. In particular, the groove 504 of the first protective sleeve 211A receives the first central rail 422A of the first track 416A. Further, the curved portion 502 of the first protective sleeve 211A corresponds to and engages the first side opening 418A defined in the cylindrical sidewall 400. The first protective sleeve 211A is removably engaged with the first track 416A at the first side 208A of the feed tube 204 and positioned at the first side opening 418A of the feed tube 204. Similarly, the second protective sleeve 211B is inserted into the second track 416B of the drop body 200. In particular, the groove 504 of the second protective sleeve 211B receives the second central rail 422B of the second track 416B. Further, the curved portion 502 of the second protective sleeve 211B corresponds to and engages the second side opening 418B defined in the cylindrical sidewall 400. The second protective sleeve 211B is removably engaged with the second track 416B at the second side 208B of the feed tube 204 and positioned at the second side opening 418B of the feed tube 204.

In this way, the drop feed line device 116 is easily serviceable, as the first and second planar circuit boards 210A, 210B and/or first and second protective sleeves 211A, 211B are easily removable and/or replaceable.

In use, the at least one emitter 212 communicates with the at least one receiver 214 through the first side opening 418A and the second side opening 418B. The first protective sleeve 211A is positioned in the first side opening 418A and the second protective sleeve 211B is positioned within the second side opening 418B. The first circuit board 210A is positioned in the first protective sleeve 211B and the second circuit board 210B is positioned in the second protective sleeve 211B. Each of the first protective sleeve 211A and the second protective sleeve 211B is open at a first end and closed at a second end opposite the first end to ensure proper alignment when the first and second planar circuit boards 210A, 210B and first and second protective sleeves 211A, 211B are fully inserted.

At least a portion of the first curved portion 424A extends into the first interior channel 206 of the feed tube 204. The first curved portion 424A helps guide falling feed 110 past the first and second protective sleeves 211A, 211B while also protecting the first and second planar circuit boards 210A, 210B from the falling feed 110.

The emitters 212 and receivers 214 of the first planar circuit board 210A and the second planar circuit board 210B are aligned toward each other so that when no feed 110 is in the feed tube 204, light from the emitters 212 is detected. Having multiple columns allows for the emitters 212 and receivers 214 to cover a greater cross-sectional area of the feed tube 204 (e.g., compared to a pattern that has overlapping or crisscrossing emission paths). Having multiple rows of emitters 212 and receivers 214 provides for coverage along an axial length of the feed tube 204. Use of multiple emitters 212 and receivers 214 helps ensure that the emitters 212 and receivers 214 are only blocked by a backup of feed 110 and not from falling feed 110 that may coincidentally block some of the emitters 212 and receivers 214. In other words, in certain embodiments, all emitters 212 and/or receivers 214 must be blocked to stop the auger drive motor 120 to ensure the blockage is from backup of feed 110 and not from falling feed 110. Further, it is noted that unlike other systems, in certain embodiments, the drop feed line device 116 detects when receivers 214 cease to receive a signal from emitters 212 (not whether receivers 214 detect a signal from emitters 212). As a result, the default state of the drop feed line device 116 is to have the auger drive motor 120 run, which means that if there is a problem or fault with the system, the result will most likely be overfilling of feed 110 (rather than underfilling), which protects the health of the livestock.

It will be apparent to those skilled in the art that various modifications and variations can be made without departing from the spirit or scope of the invention.

Many modifications and other embodiments of the embodiments set forth herein will come to mind to one skilled in the art to which the embodiments pertain having the benefit of the teachings presented in the foregoing descriptions and the associated drawings. Therefore, it is to be understood that the description and claims are not to be limited to the specific embodiments disclosed and that modifications and other embodiments are intended to be included within the scope of the appended claims. It is intended that the embodiments cover the modifications and variations of the embodiments provided they come within the scope of the appended claims and their equivalents. Although specific terms are employed herein, they are used in a generic and descriptive sense only and not for purposes of limitation.

What is claimed is:

1. A drop feed line device, comprising:
a drop body comprising an electrical box and a feed tube defining an interior channel;
a first planar circuit board positioned at a first side of the feed tube, the first planar circuit board in electronic communication with electronic components within the electrical box, the first planar circuit board comprising at least one emitter; and
a second planar circuit board positioned at a second side of the feed tube, the second planar circuit board in electronic communication with the electronic components within the electrical box, the second planar circuit board comprising at least one receiver to electronically communicate with the at least one emitter across the interior channel of the feed tube.

2. The drop feed line device of claim 1,
further comprising a first protective sleeve positioned at the first side of the feed tube and a second protective sleeve positioned at the second side of the feed tube;
wherein the first planar circuit board is positioned in the first protective sleeve and the second planar circuit board is positioned in the second protective sleeve.

3. The drop feed line device of claim 2, wherein the first protective sleeve is cylindrically shaped with a generally planar face and a curved portion, the first protective sleeve open at a first end and closed at a second end opposite the first end, at least a portion of the curved portion extending into an interior of the feed tube.

4. The drop feed line device of claim 1,
wherein the feed tube of the drop body further comprises a first side opening and a second side opening opposite the first side opening; and
wherein the first planar circuit board is positioned proximate the first side opening and the second planar circuit board is positioned proximate the second side opening.

5. The drop feed line device of claim 4, wherein the at least one emitter communicates with the at least one receiver through the first side opening and the second side opening.

6. The drop feed line device of claim 4,
further comprising a first protective sleeve positioned in the first side opening and a second protective sleeve positioned within the second side opening;
wherein the first planar circuit board is positioned in the first protective sleeve and the second planar circuit board is positioned in the second protective sleeve.

7. The drop feed line device of claim 1, wherein the at least one emitter comprises an infrared emitter and the at least one receiver comprises an infrared receiver.

8. The drop feed line device of claim 1, wherein the first planar circuit board comprises at least one receiver and the second planar circuit board comprises at least one emitter.

9. The drop feed line device of claim 1,
wherein the at least one emitter of the first planar circuit board comprises a plurality of emitters including a first top row of infrared emitters and a first bottom row of infrared emitters; and
wherein the at least one receiver of the second planar circuit board comprises a plurality of receivers including a second top row of infrared receivers and a second bottom row of infrared receivers.

10. The drop feed line device of claim 9, further comprising a feed controller positioned within the electrical box, the feed controller configured to:
determine if all of the plurality of emitters of the first planar circuit board cease to communicate with all of the plurality of receivers of the second planar circuit board; and
transmit a signal to cease operation of an auger motor filling a drop feed line upon determining that all of the plurality of emitters of the first circuit board cease to communicate with all of the plurality of receivers of the second circuit board.

11. The drop feed line device of claim 1, wherein the electrical box further comprises a display configured to change color to communicate a state of operation of the drop feed line device.

12. A drop feed line device, comprising:
a drop body comprising:
an electrical box including a first track and a second track; and
a feed tube defining an interior channel, the feed tube comprising a first side opening and a second side opening opposite the first side opening, the first side opening proximate the first track and the second side opening proximate the second track;
a first protective sleeve removably engaged with the first track at a first side of the feed tube and positioned at the first side opening of the feed tube;
a second protective sleeve removably engaged with the second track at a second side of the feed tube and positioned at the second side opening of the feed tube;
a first planar circuit board positioned in the first protective sleeve at the first side of the feed tube, the first planar circuit board in electronic communication with electronic components within the electrical box, the first planar circuit board comprising at least one infrared emitter; and
a second planar circuit board positioned in the second protective sleeve at the second side of the feed tube, the second planar circuit board in electronic communication with the electronic components within the electrical box, the second planar circuit board comprising at least one infrared receiver to electronically communicate with the at least one infrared emitter across the interior channel of the feed tube.

13. The drop feed line device of claim 12, wherein the first protective sleeve is cylindrically shaped with a generally planar face and a curved portion, the first protective sleeve open at a first end and closed at a second end opposite the first end, at least a portion of the curved portion extending into an interior of the feed tube.

14. The drop feed line device of claim 12, wherein the first planar circuit board comprises at least one receiver and the second planar circuit board comprises at least one emitter.

15. The drop feed line device of claim 12,
wherein the at least one emitter of the first planar circuit board comprises a plurality of emitters including a first top row of infrared emitters and a first bottom row of infrared emitters; and
wherein the at least one receiver of the second planar circuit board comprises a plurality of receivers including a second top row of infrared receivers and a second bottom row of infrared receivers.

16. The drop feed line device of claim 12, further comprising a feed controller positioned within the electrical box, the feed controller configured to:
determine if all of the plurality of emitters of the first planar circuit board cease to communicate with all of the second plurality of infrared receivers of the second planar circuit board; and
transmit a signal to cease operation of an auger motor filling a drop feed line upon determining that all of the plurality of emitters of the first circuit board cease to communicate with all of the plurality of receivers of the second circuit board.

17. The drop feed line device of claim 12, wherein the electrical box further comprises a display configured to change color to communicate a state of operation of the drop feed line device.

18. A feed system, comprising:
a drop feed line;
an auger motor configured to transmit feed to and through the drop feed line; and
a drop feed line device positioned in and defining at least a portion of the drop feed line, the drop feed line device comprising:
a drop body comprising an electrical box and a feed tube defining an interior channel;
a first planar circuit board positioned at a first side of the feed tube, the first planar circuit board in electronic communication with electronic components within the electrical box, the first planar circuit board comprising at least one emitter;
a second planar circuit board positioned at a second side of the feed tube, the second planar circuit board in electronic communication with the electronic components within the electrical box, the second planar circuit board comprising at least one receiver to electronically communicate with the at least one emitter across the interior channel of the feed tube; and
a feed controller positioned within the electrical box, the feed controller configured to:
determine if all of the at least one emitter of the first planar circuit board cease to communicate with all of the at least one receiver of the second planar circuit board; and
transmit a signal to the auger motor to cease operation of the auger motor filling the drop feed line upon determining that all of the at least one emitters cease to communicate with all of the at least one receivers.

19. The feed system of claim 18,
further comprising a first protective sleeve positioned at the first side of the feed tube and a second protective sleeve positioned at the second side of the feed tube;
wherein the feed tube of the drop body further comprises a first side opening and a second side opening opposite the first side opening; and
wherein the first planar circuit board is positioned in the first protective sleeve proximate the first side opening and the second planar circuit board positioned in the second protective sleeve proximate the second side opening.

20. The feed system of claim 18, wherein the at least one emitter comprises an infrared emitter and the at least one receiver comprises an infrared receiver.

21. The feed system of claim 18, wherein the first planar circuit board comprises at least one receiver and the second planar circuit board comprises at least one emitter.

22. The feed system of claim 18,
wherein the at least one emitter of the first planar circuit board comprises a plurality of emitters including a first top row of infrared emitters and a first bottom row of infrared emitters; and
wherein the at least one receiver of the second planar circuit board comprises a plurality of receivers including a second top row of infrared receivers and a second bottom row of infrared receivers.

23. The feed system of claim 18, wherein the electrical box further comprises a display configured to change color to communicate a state of operation of the drop feed line device.
